(19) United States
(12) Patent Application Publication
(10) Pub. No.: US 2026/0237565 A1
(43) Pub. Date: Aug. 13, 2026

(54) CAPACITOR AND MEMORY DEVICE INCLUDING THE SAME, METHOD OF MANUFACTURING CAPACITOR, METHOD OF MANUFACTURING MEMORY DEVICE

(71) Applicant: EGTM Co., Ltd., Suwon-si (KR)

(72) Inventors: Kyu Ho CHO, Suwon-si (KR); Hyun Ju JUNG, Suwon-si (KR); Ju Hwan JEONG, Suwon-si (KR); Han Bin LEE, Suwon-si (KR); Hyeon Sik CHO, Suwon-si (KR); Ji Yeon HAN, Suwon-si (KR); MYEONG IL KIM, Suwon-si (KR); Sung Jun JI, Suwon-si (KR)

(73) Assignee: EGTM Co., Ltd., Suwon-si (KR)

(21) Appl. No.: 19/537,019

(22) Filed: Feb. 11, 2026

(30) Foreign Application Priority Data
Feb. 11, 2025 (KR) 10-2025-0017654

(51) Int. Cl. H01G 4/30; H01G 4/008; H01G 4/12

(52) U.S. Cl. CPC H01G 4/30; H01G 4/008; H01G 4/1227

(57) ABSTRACT

According to an embodiment of the present invention, a capacitor comprises: a first electrode; a second electrode spaced apart from the first electrode; and an interface structure disposed between the first electrode and the second electrode, wherein the interface structure comprises: a dielectric film disposed between the first electrode and the second electrode; a first interface film disposed between the first electrode and the dielectric film; and a second interface film disposed between the second electrode and the dielectric film.

### CROSS-REFERENCE TO RELATED APPLICATION

This application claims priority to and the benefit of Korean Patent Application No. 10-2025-0017654, filed on Feb. 11, 2025, the disclosure of which is incorporated herein by reference in its entirety.

### BACKGROUND

### 1. Technical Field

The present invention relates to a capacitor and a memory device including the same, and a method of manufacturing a capacitor and a method of manufacturing a memory device, and more particularly, to a capacitor using a dielectric film comprising oxides having a tetravalent element and a trivalent element as central elements, respectively, and a memory device including the same, and a method of manufacturing a capacitor and a method of manufacturing a memory device.

### 2. Related Art

With the development of integrated circuit electronic devices, improving device performance and miniaturization have become important challenges. As the size of electronic devices decreases, it is required to reduce the thickness of dielectric films to maintain the capacitance of capacitors. However, as the dielectric film becomes thinner, there is a problem that leakage current increases, thereby degrading the reliability of the device.

To address this, high-k materials are being used as dielectrics. High-k materials are effective in improving electrical performance by maintaining a high dielectric constant even at low thicknesses, while simultaneously reducing leakage current. Therefore, high performance and reliability can be maintained even in miniaturized electronic devices.

However, as the thickness of high-k materials becomes thinner, effects occurring at surfaces or interfaces may have a greater influence on the overall properties. For this reason, securing a high-k dielectric thin film having a thin thickness while possessing high-quality desired characteristics is a very important technical challenge.

### SUMMARY

An object of the present invention is to provide a capacitor capable of improving characteristics of a thin film, a memory device including the same, a method of manufacturing a capacitor, and a method of manufacturing a memory device.

Other objects of the present invention will become more apparent from the following detailed description.

The problems to be solved by the present invention are not limited to the above-mentioned problems, and problems not mentioned will be clearly understood by those skilled in the art to which the present invention belongs from the present specification and the accompanying drawings.

According to an embodiment of the present invention, a capacitor comprises: a first electrode; a second electrode spaced apart from the first electrode; and an interface structure disposed between the first electrode and the second electrode, wherein the interface structure comprises: a dielectric film disposed between the first electrode and the second electrode; a first interface film disposed between the first electrode and the dielectric film; and a second interface film disposed between the second electrode and the dielectric film, wherein the dielectric film comprises: a first dielectric film comprising an oxide having a first metal as a central element, the first metal being a tetravalent element; a second dielectric film comprising an oxide having a second metal as a central element, the second metal being a trivalent element; a third dielectric film comprising an oxide having the first metal as a central element, the first metal being a tetravalent element; and a fourth dielectric film comprising an oxide having the second metal as a central element, the second metal being a trivalent element, wherein each of the first and third dielectric films has a thickness of 10 to 30 Å, and wherein a sum of thicknesses of the first to fourth dielectric films is 40 to 60 Å.

The trivalent element may be aluminum (Al).

The first and third dielectric films may comprise at least one of hafnium oxide and zirconium oxide, and the second and fourth dielectric films may comprise aluminum oxide.

The first interface film and the second interface film may comprise an oxide having a third metal as a central element, the third metal being a pentavalent element.

The pentavalent element may be niobium (Nb), tantalum (Ta), or vanadium (V).

Each of the second and fourth dielectric films may have a thickness of 0.3 to 3 Å.

Each of the first and second electrodes may comprise a metal or a metal nitride.

According to an embodiment of the present invention, a memory device may comprise the capacitor described above.

According to an embodiment of the present invention, a method of manufacturing a capacitor comprises: forming a first interface film on a first electrode; sequentially forming first to fourth dielectric films on the first interface film; forming a second interface film on the fourth dielectric film; and forming a second electrode on the second interface film, wherein the first and third dielectric films have a first metal as a central element, the first metal being a tetravalent element, and each of the first and third dielectric films has a thickness of 10 to 30 Å, wherein the second and fourth dielectric films have a second metal as a central element, the second metal being a trivalent element, and wherein a sum of thicknesses of the first to fourth dielectric films is 40 to 60 Å.

The forming of the second interface film may comprise: initially forming the second interface film to a thickness of 30 Å or more; and finally forming the second interface film to a thickness of 10 Å or less by etching the initially formed second interface film.

The first interface film may be formed to a thickness of 10 Å or less.

According to an embodiment of the present invention, a method of manufacturing a memory device may comprise the method of manufacturing a capacitor described above.

The technical solutions of the present invention are not limited to the above-mentioned solutions, and solutions not mentioned will be clearly understood by those skilled in the art to which the present invention belongs from the present specification and the accompanying drawings.

According to an embodiment of the present invention, a capacitor may have high capacitance and low leakage current characteristics by using a dielectric film comprising oxides having a tetravalent element and a trivalent element as central elements, respectively.

In addition, a semiconductor device including the capacitor as described above can easily achieve high integration density, thereby contributing to miniaturization of electronic devices.

The effects of the present invention are not limited to the above-mentioned effects, and effects not mentioned will be clearly understood by those skilled in the art to which the present invention belongs from the present specification and the accompanying drawings.

### BRIEF DESCRIPTION OF DRAWINGS

FIG. 1 is a cross-sectional view schematically illustrating a capacitor according to an embodiment of the present invention.

FIGS. 2 to 7 are graphs showing crystal structures of Hf oxide.

FIG. 8 is a graph showing crystal structures of Hf oxide according to thicknesses of interface films and dielectric films.

FIG. 9 is a TEM photograph showing before and after etching of the second interface film.

FIGS. 10 and 11 are graphs showing dielectric constants for Example 1 and Example 2.

### DESCRIPTION OF EXAMPLE EMBODIMENTS

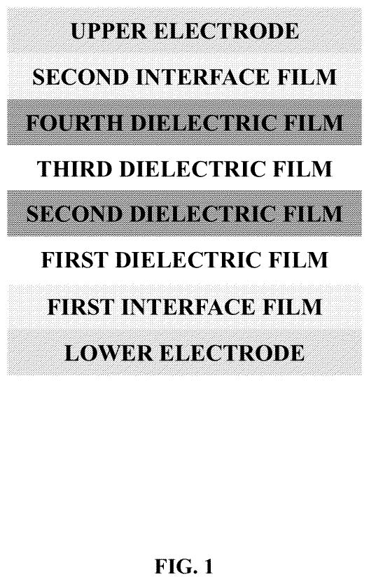

Hereinafter, preferred embodiments of the present invention will be described in more detail with reference to the accompanying FIGS. 1 to 11. The embodiments of the present invention may be modified in various forms, and the scope of the present invention should not be construed as being limited to the embodiments described below. The present embodiments are provided to more fully describe the present invention to those of ordinary skill in the art to which the present invention pertains. Accordingly, the shapes of elements shown in the drawings may be exaggerated for emphasis of clearer description.

FIG. 1 is a cross-sectional view schematically illustrating a capacitor according to an embodiment of the present invention. As shown in FIG. 1, the capacitor comprises a lower electrode, an upper electrode spaced apart from the lower electrode, and an interface structure disposed between the lower electrode and the upper electrode, wherein the interface structure may comprise first and second interface films and first to fourth dielectric films. The first interface film may be disposed between the lower electrode and the first dielectric film, and the second interface film may be disposed between the upper electrode and the fourth dielectric film.

The lower electrode may comprise a metal, a metal nitride, a metal oxide, or a combination thereof. For example, the lower electrode may comprise a metal such as titanium (Ti), nickel (Ni), aluminum (Al), tantalum (Ta), tungsten (W), platinum (Pt), palladium (Pd), gold (Au), iridium (Ir), rhodium (Rh), molybdenum (Mo), vanadium (V), or niobium (Nb), or a nitride of Ti, a nitride of Ni, a nitride of Al, a nitride of Ta, a nitride of W, a nitride of Pt, a nitride of Pd, a nitride of Au, a nitride of Ir, a nitride of Rh, a nitride of Mo, a nitride of V, or a nitride of Nb. The thickness of the lower electrode may be, for example, 10 Å or more and 200 Å or less.

The first to fourth dielectric films may comprise, for example, a metal oxide composed of ZrO₂, HfO₂, Al₂O₃, or a combination thereof. Specifically, the first and third dielectric films may comprise at least one oxide (for example, hafnium oxide or zirconium oxide) having a metal that is a tetravalent element (for example, Hf, Zr) as a central element, and the second and fourth dielectric films may comprise at least one oxide (for example, aluminum oxide) having a metal that is a trivalent element (for example, Al) as a central element.

Each of the first and third dielectric films may have a thickness of 10 Å or more and 30 Å or less, and each of the second and fourth dielectric films may have a thickness of 0.3 Å or more and 3 Å or less.

The first and second interface films may comprise an oxide having a third metal as a central element, the third metal being a pentavalent element. The pentavalent element may include niobium (Nb), tantalum (Ta), or vanadium (V). Each of the first and second interface films may have a thickness of 1 Å or more and 10 Å or less.

The upper electrode may comprise the same material as the lower electrode. The upper electrode may comprise a metal, a metal nitride, a metal oxide, or a combination thereof. For example, the upper electrode may comprise a metal such as titanium (Ti), nickel (Ni), aluminum (Al), tantalum (Ta), tungsten (W), platinum (Pt), palladium (Pd), gold (Au), iridium (Ir), rhodium (Rh), molybdenum (Mo), vanadium (V), or niobium (Nb), or a nitride of Ti, a nitride of Ni, a nitride of Al, a nitride of Ta, a nitride of W, a nitride of Pt, a nitride of Pd, a nitride of Au, a nitride of Ir, a nitride of Rh, a nitride of Mo, a nitride of V, or a nitride of Nb. The thickness of the upper electrode may be, for example, 20 Å or more and 50 Å or less.

### Comparative Example 1

On the lower electrode, Hf oxide was formed to 40 Å as a first dielectric film, Al oxide was formed to 0.3 Å or more and 3 Å or less as a second dielectric film on the first dielectric film, Hf oxide was formed to 30 Å as a third dielectric film on the second dielectric film, and Al oxide was formed to 0.3 Å or more and 3 Å or less as a fourth dielectric film on the third dielectric film.

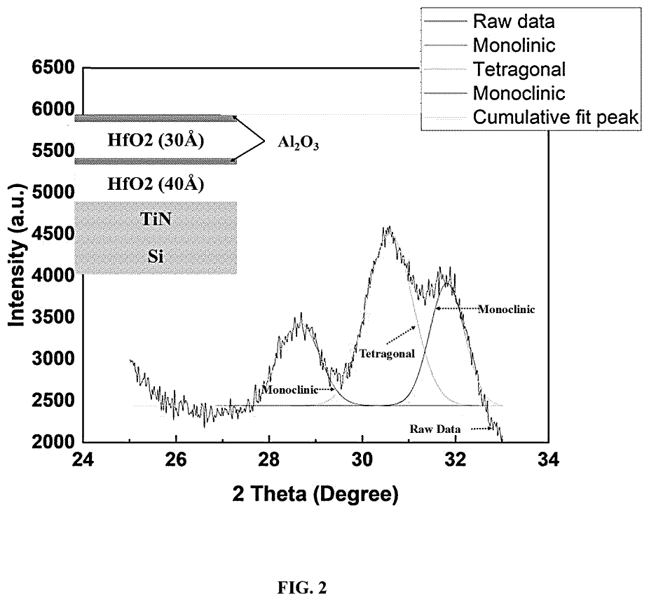

In this case, the thickness of the first to fourth dielectric films is 70 Å or more and 80 Å or less, and the crystal structure of Hf oxide is confirmed to have a tetragonal ratio of 51.0% compared to monoclinic (FIG. 2).

### Comparative Example 2

On the lower electrode, Nb oxide was formed to 2 Å as a first interface film, Hf oxide was formed to 40 Å as a first dielectric film on the first interface film, Al oxide was formed to 0.3 Å or more and 3 Å or less as a second dielectric film on the first dielectric film, Hf oxide was formed to 30 Å as a third dielectric film on the second dielectric film, and Al oxide was formed to 0.3 Å or more and 3 Å or less as a fourth dielectric film on the third dielectric film.

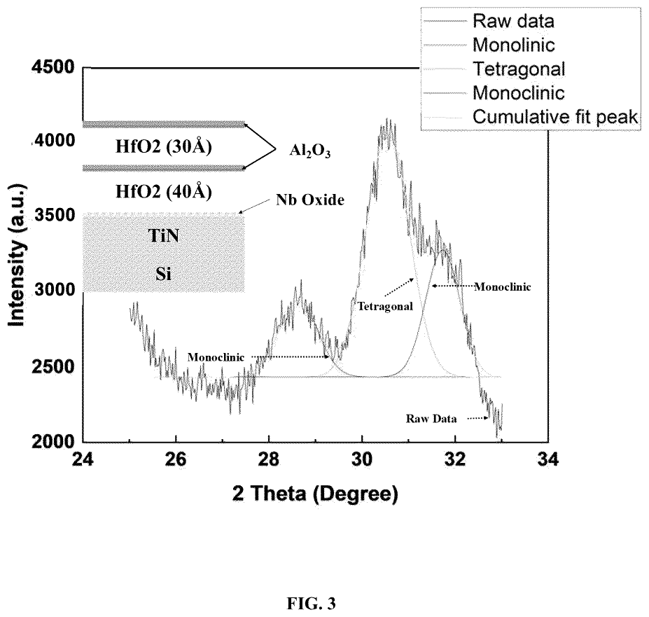

In this case, the thickness of the first to fourth dielectric films is 70 Å or more and 80 Å or less, and the crystal structure of Hf oxide is confirmed to have a tetragonal ratio of 58.9% compared to monoclinic (FIG. 3).

### Comparative Example 3

On the lower electrode, Nb oxide was formed to 2 Å as a first interface film, Hf oxide was formed to 40 Å as a first dielectric film on the first interface film, Al oxide was formed to 0.3 Å or more and 3 Å or less as a second dielectric film on the first dielectric film, Hf oxide was formed to 30 Å as a third dielectric film on the second dielectric film, Al oxide was formed to 0.3 Å or more and 3 Å or less as a fourth dielectric film on the third dielectric film, and Nb oxide was formed to 2 Å as a second interface film on the fourth dielectric film.

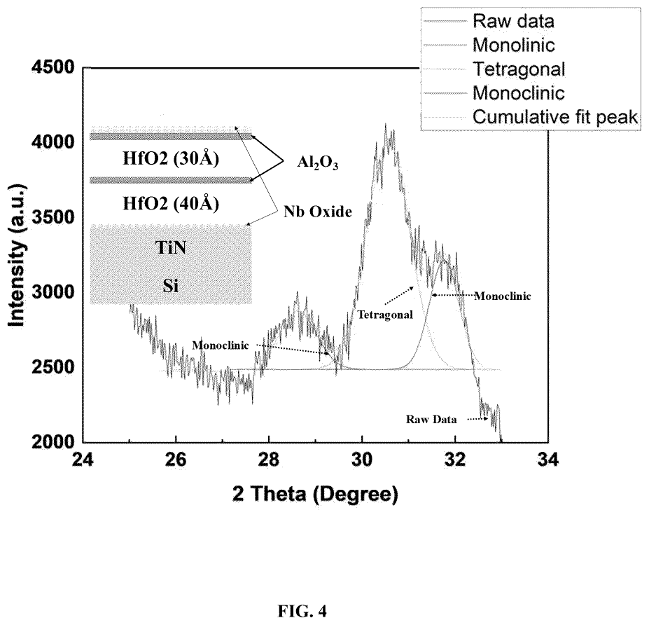

In this case, the thickness of the first to fourth dielectric films is 70 Å or more and 80 Å or less, and the crystal structure of Hf oxide is confirmed to have a tetragonal ratio of 64.4% compared to monoclinic (FIG. 4).

### Comparative Example 4

On the lower electrode, Nb oxide was formed to 2 Å as a first interface film, Hf oxide was formed to 40 Å as a first dielectric film on the first interface film, Al oxide was formed to 0.3 Å or more and 3 Å or less as a second dielectric film on the first dielectric film, Hf oxide was formed to 30 Å as a third dielectric film on the second dielectric film, Al oxide was formed to 0.3 Å or more and 3 Å or less as a fourth dielectric film on the third dielectric film, and Nb oxide was formed to 30 Å as a second interface film on the fourth dielectric film.

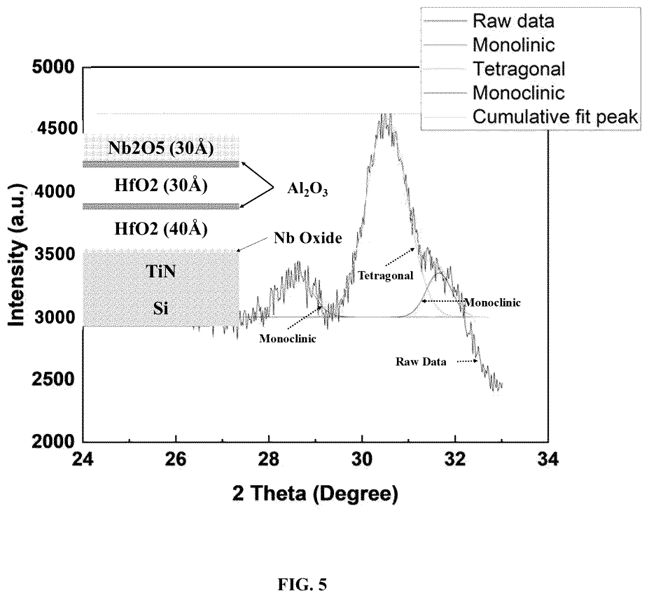

In this case, the thickness of the first to fourth dielectric films is 70 Å or more and 80 Å or less, and the crystal structure of Hf oxide is confirmed to have a tetragonal ratio of 76.7% compared to monoclinic (FIG. 5).

### Example 1

On the lower electrode, Nb oxide was formed to 2 Å as a first interface film, Hf oxide was formed to 30 Å as a first dielectric film on the first interface film, Al oxide was formed to 0.3 Å or more and 3 Å or less as a second dielectric film on the first dielectric film, Hf oxide was formed to 20 Å as a third dielectric film on the second dielectric film, Al oxide was formed to 0.3 Å or more and 3 Å or less as a fourth dielectric film on the third dielectric film, and Nb oxide was formed to 2 Å as a second interface film on the fourth dielectric film.

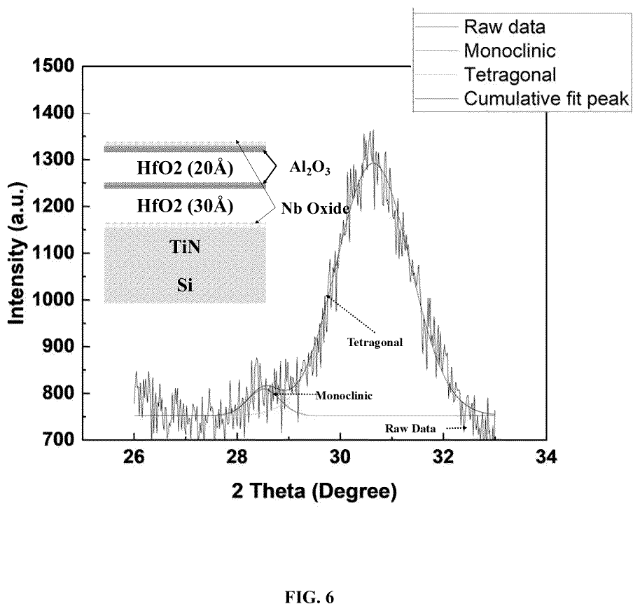

In this case, the thickness of the first to fourth dielectric films is 50 Å or more and 60 Å or less, and the crystal structure of Hf oxide is confirmed to have a tetragonal ratio of 95.7% compared to monoclinic (FIG. 6).

### Example 2

On the lower electrode, Nb oxide was formed to 2 Å as a first interface film, Hf oxide was formed to 30 Å as a first dielectric film on the first interface film, Al oxide was formed to 0.3 Å or more and 3 Å or less as a second dielectric film on the first dielectric film, Hf oxide was formed to 20 Å as a third dielectric film on the second dielectric film, Al oxide was formed to 0.3 Å or more and 3 Å or less as a fourth dielectric film on the third dielectric film, and Nb oxide was formed to 30 Å as a second interface film on the fourth dielectric film.

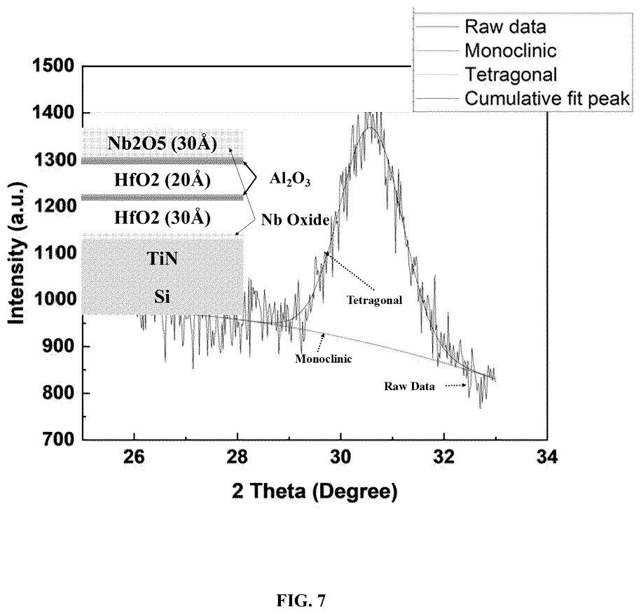

In this case, the thickness of the first to fourth dielectric films is 50 Å or more and 60 Å or less, and the crystal structure of Hf oxide is confirmed to have a tetragonal ratio of 99.5% compared to monoclinic (FIG. 7).

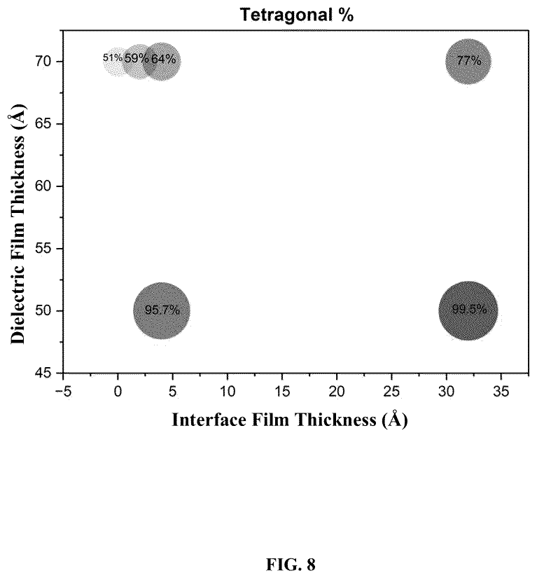

According to the above-described embodiments, as the thickness of the second interface film increases, tetragonal crystallization of the dielectric film can be promoted. This crystallization promotion effect is greater when the interface film is formed thicker in a dielectric film having a thin thickness, because the effect occurring at the interface acts more significantly as the thickness of the dielectric film becomes thinner (FIG. 8).

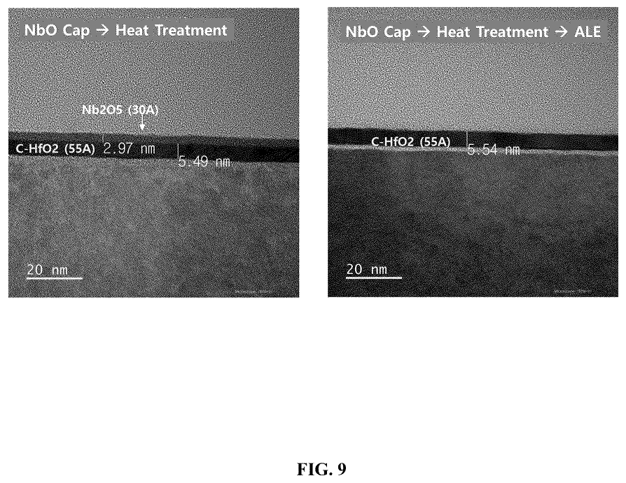

However, if the thickness of the second interface film becomes too thick, it may be difficult to form a capacitor having high integration density, and the electrical characteristics of the capacitor may be deteriorated. Therefore, the capacitors according to the above embodiments may be formed by forming the second interface film to a thickness of 30 Å or more to promote tetragonal crystallization of the dielectric film, and then etching the thickness of the second interface film to within 10 Å through a subsequent etching process (FIG. 9).

Through this, a dielectric film having a thin thickness using a high-k material can be formed, thereby improving the electrical characteristics of the capacitor to an excellent level.

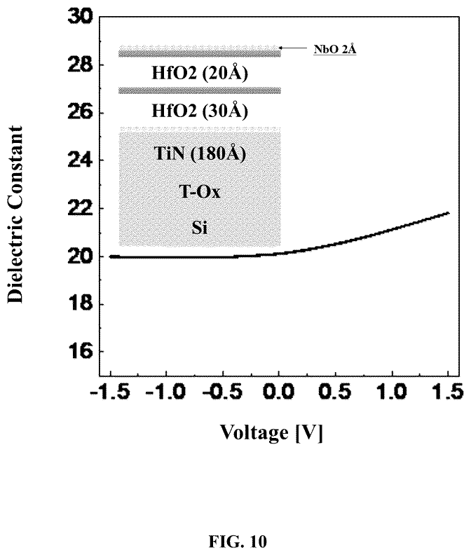

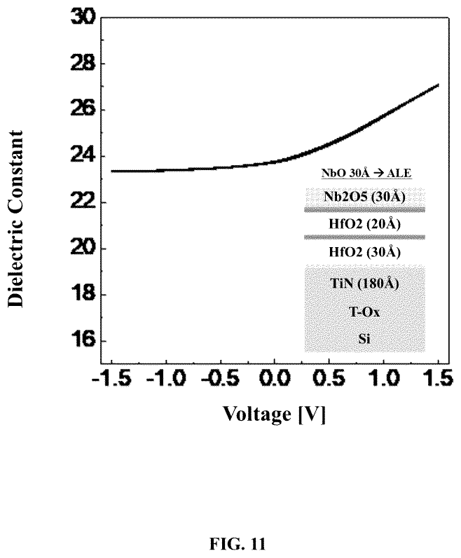

FIGS. 10 and 11 are graphs showing dielectric constants for Example 1 and Example 2, and Table 1 below shows the dielectric constants for Example 1 and Example 2.

TABLE 1

| Item | Example 1 | Example 2 |
|---|---|---|
| Dielectric constant @0 V | 20.11 | 23.72 |
| Current dens. @+0.8 V [A/cm²] | 3.11E−8 | 3.44E−8 |
| Current dens. @−0.8 V [A/cm²] | 4.17E−8 | 4.02E−8 |

Specifically, in the case of Example 1, the dielectric constant is confirmed to be 20.11, and in the case of Example 2, the dielectric constant is confirmed to be 23.72. That is, Example 2 showed an improvement in dielectric constant of approximately 18% compared to Example 1 in which the second interface film is relatively thin, and the leakage current was confirmed to be at an equivalent level.

Although the present invention has been described in detail through the embodiments above, other forms of embodiments are also possible. Therefore, the technical spirit and scope of the claims described below are not limited to the embodiments.

What is claimed is:

1. A capacitor comprising:
a first electrode;
a second electrode spaced apart from the first electrode; and
an interface structure disposed between the first electrode and the second electrode,
wherein the interface structure comprises:
a dielectric film disposed between the first electrode and the second electrode;
a first interface film disposed between the first electrode and the dielectric film; and
a second interface film disposed between the second electrode and the dielectric film,
wherein the dielectric film comprises:
a first dielectric film comprising an oxide having a first metal as a central element, the first metal being a tetravalent element;
a second dielectric film comprising an oxide having a second metal as a central element, the second metal being a trivalent element;
a third dielectric film comprising an oxide having the first metal as a central element, the first metal being a tetravalent element; and
a fourth dielectric film comprising an oxide having the second metal as a central element, the second metal being a trivalent element,
wherein each of the first and third dielectric films has a thickness of 10 to 30 Å, and
wherein a sum of thicknesses of the first to fourth dielectric films is 40 to 60 Å.

2. The capacitor of claim 1, wherein the trivalent element is aluminum (Al).

3. The capacitor of claim 1, wherein the first and third dielectric films comprise at least one of hafnium oxide and zirconium oxide, and wherein the second and fourth dielectric films comprise aluminum oxide.

4. The capacitor of claim 1, wherein the first interface film and the second interface film comprise an oxide having a third metal as a central element, the third metal being a pentavalent element.

5. The capacitor of claim 4, wherein the pentavalent element is niobium (Nb), tantalum (Ta), or vanadium (V).

6. The capacitor of claim 1, wherein each of the second and fourth dielectric films has a thickness of 0.3 to 3 Å.

7. The capacitor of claim 1, wherein each of the first and second electrodes comprises a metal or a metal nitride.

8. A memory device comprising the capacitor of claim 1.

9. A method of manufacturing a capacitor, comprising:
forming a first interface film on a first electrode;
sequentially forming first to fourth dielectric films on the first interface film;
forming a second interface film on the fourth dielectric film; and
forming a second electrode on the second interface film,
wherein the first and third dielectric films have a first metal as a central element, the first metal being a tetravalent element, and each of the first and third dielectric films has a thickness of 10 to 30 Å,
wherein the second and fourth dielectric films have a second metal as a central element, the second metal being a trivalent element, and
wherein a sum of thicknesses of the first to fourth dielectric films is 40 to 60 Å.

10. The method of claim 9, wherein the forming of the second interface film comprises: initially forming the second interface film to a thickness of 30 Å or more; and finally forming the second interface film to a thickness of 10 Å or less by etching the initially formed second interface film.

11. The method of claim 10, wherein the first interface film is formed to a thickness of 10 Å or less.

12. A method of manufacturing a memory device, comprising the method of manufacturing a capacitor of claim 9.
